(19) United States
(12) Patent Application Publication
(10) Pub. No.: US 2003/0132498 A1
(43) Pub. Date: Jul. 17, 2003

(54) Photovoltaic device and making of the same

(75) Inventors: Tsuyoshi Uematsu, Kodaira (JP); Ken Tsutsui, Hinode (JP); Toshio Johge, Hitachi (JP)

Correspondence Address: Miles & Stockbridge P.C., Suite 500, 1751 Pinnacle Drive, McLean, VA, 22102-3833, US

(73) Assignee: Hitachi, Ltd.

(21) Appl. No.: 10/193,924

(22) Filed: Jul. 15, 2002

(30) Foreign Application Priority Data
Jan. 16, 2002 (JP) 2002-007220

(51) Int. Cl. H01L 29/04; H01L 31/036; H01L 21/00

(52) U.S. Cl. 257/461; 257/53; 257/54; 257/449; 438/570; 438/48

(57) ABSTRACT

The prevention of the deterioration of the minority carrier lifetime of a semiconductor substrate can be achieved by patterning the material of an impurity diffusion protecting layer on the surface of a semiconductor substrate by a making except a thermal oxidation process of the semiconductor substrate, for example by printing and firing paste material or by depositing paste material using a mask by CVD and forming a diffusion layer in the shape of an inverted pattern of the impurity diffusion protecting layer. Also, a low-priced photovoltaic device the photo-electric conversion efficiency of which is high can be manufactured by patterning and forming them.

### BACKGROUND OF THE INVENTION

1. Field of the Invention

The present invention relates to a photovoltaic device and the making of the same, particularly relates to a photovoltaic device suitable for manufacturing using the diffusion of impurities and the making of the same.

2. Description of the Related Art

For a photovoltaic device manufactured using the diffusion of impurities, photovoltaic devices having sectional structures shown in FIGS. 13A to 13F are known. The photovoltaic device having the structure shown in FIG. 13D is shown in FIG. 1C on pages from the 45th to the 48th of the 11th E.C. PHOTOVOLTAIC SOLAR ENERGY CONFERENCE) for example.

A reference number 1 in FIG. 13 denotes a P-type silicon semiconductor substrate, 4 and 8 denote an N-type impurity layer, 6 denotes a P-type impurity layer and 5, 7 and 10 denote an electrode.

Using the photovoltaic device described in the prior art and shown in FIG. 13D as a typical example, the manufacturing process will be described below, referring to FIGS. 14A to 14D.

First, as shown in FIG. 14A, a first SiO₂ impurity diffusion protecting layer 11 is formed on the surface of a P-type silicon semiconductor substrate 1 using a thermal oxidation process at approximately 100 C. and photolithography, and a P-type impurity layer 6 is formed in an opening (not shown) by gas phase diffusion using gas 3 including P-type impurities in the silicon semiconductor substrate 1 as shown in FIG. 14B.

Next, as shown in FIG. 14B, the first SiO₂ impurity diffusion protecting layer 11 is removed and after a second SiO₂ impurity diffusion protecting layer 12 is formed using a thermal oxidation process and photolithography, an N-type impurity layer 4 is formed in an opening (not shown) by gas phase diffusion using gas 3 including n-type impurities in the silicon semiconductor substrate 1 as shown in FIG. 14C. Next, the second SiO₂ impurity diffusion protecting layer 12 is removed.

Afterward, as shown in FIG. 14D, silver electrodes 5 and 7 are formed using screen printing as respective electrodes of the P-type impurity layer 6 and the N-type impurity layer 4.

In the manufacturing process, the semiconductor substrate 1 is exposed to high temperature of approximately 1000 C. by thermal oxidation when the two types of (the first and second) SiO₂ impurity diffusion protecting layers 11 and 12 are formed and the minority carrier lifetime of the semiconductor substrate is deteriorated. Hereby, it is known that a problem that the photo-electric conversion efficiency of the photovoltaic device is remarkably deteriorated is caused.

This problem exists in not only the photovoltaic device having the structure shown in FIG. 13D but the photovoltaic devices having other structures shown in FIG. 13. It is also known that as the second SiO₂ impurity diffusion protecting layer 12 is formed on the P-type impurity layer 6 as shown in FIG. 14B, a problem that impurities in the P-type impurity layer 6 are diffused again in the formation and an impurity profile changes is caused.

These problems also occur in the photovoltaic devices shown in FIGS. 13C, 13E and 13F in addition to the photovoltaic device shown in FIG. 13D out of the photovoltaic devices shown in FIG. 13 and make the design of the photovoltaic device difficult.

### SUMMARY OF THE INVENTION

Therefore, the object of the invention is to solve these problems of the conventional type, concretely to provide a photovoltaic device and the making of the same that prevent the minority carrier lifetime of a semiconductor substrate from being deteriorated and that have high photo-electric conversion efficiency.

The object can be achieved by the making of the photovoltaic device including a process for printing or depositing material with a pattern for an impurity diffusion protecting layer on the surface of a semiconductor substrate and forming the impurity diffusion protecting layer and a process for forming a diffusion layer having an inverted pattern of the impurity diffusion protecting layer by diffusing impurities in the semiconductor substrate using the impurity diffusion protecting layer as a mask. For a method of diffusion for forming the diffusion layer having the inverted pattern of the impurity diffusion protecting layer, well-known diffusion technique such as gas phase diffusion using liquid and gas diffusion sources, implantation and further, plasma diffusion can be adopted.

The photovoltaic device according to the invention is characterized in that the impurity diffusion protecting layer is formed without exposing the semiconductor substrate to high temperature of approximately 1000 C. as in the prior art and is formed by printing or depositing in a pattern, as a result, the minority carrier lifetime of the semiconductor substrate can be prevented from being deteriorated and the photovoltaic device high in photo-electric conversion efficiency is acquired.

According to the invention, as the patterned impurity diffusion protecting layer can be formed in one process without using a pattern forming process using a thermal oxidation process and a photolithographic process which have been respectively heretofore adopted, the manufacturing process can be greatly simplified.

It is desirable that paste is made of high-viscosity material including silicon oxide for inorganic material and unnecessary impurities which are easily diffused in a semiconductor substrate made of silicon and others and which have an effect upon a conductive type and impurities such as heavy metal that deteriorates minority carrier lifetime are not included. For the caking additive of the high-viscosity material, an organic or inorganic resin component compatible with pattern formation by screen printing for example is used. A patterned printed or deposited layer is fired at the temperature of approximately 400 C. to be the impurity diffusion protecting layer.

### BRIEF DESCRIPTION OF THE DRAWINGS

FIG. 1 are manufacturing process drawings schematically showing one sectional structure of a photovoltaic device according to the invention;

FIG. 2 are manufacturing process drawings schematically showing one sectional structure of the photovoltaic device according to the invention;

FIG. 3 are manufacturing process drawings schematically showing one sectional structure equivalent to a first embodiment of the photovoltaic device according to the invention;

FIG. 4 are manufacturing process drawings schematically showing one sectional structure equivalent to a second embodiment of the photovoltaic device according to the invention;

FIG. 5 are manufacturing process drawings schematically showing one sectional structure equivalent to the second embodiment of the photovoltaic device according to the invention;

FIG. 6 are manufacturing process drawings schematically showing one sectional structure equivalent to a third embodiment of the photovoltaic device according to the invention;

FIG. 7 are manufacturing process drawings schematically showing one sectional structure equivalent to a fourth embodiment of the photovoltaic device according to the invention;

FIG. 8 are manufacturing process drawings schematically showing one sectional structure equivalent to the fourth embodiment of the photovoltaic device according to the invention;

FIG. 9 are manufacturing process drawings schematically showing one sectional structure equivalent to a fifth embodiment of the photovoltaic device according to the invention;

FIG. 10 are manufacturing process drawings schematically showing one sectional structure equivalent to a sixth embodiment of the photovoltaic device according to the invention;

FIG. 11 are explanatory drawings schematically showing the plane pattern structure of an impurity diffusion protecting layer of the photovoltaic device according to the invention;

FIG. 12 are sectional views of a substrate schematically explaining the irregularities of the surface of the substrate of the photovoltaic device according to the invention;

FIG. 13 are sectional views showing one manufacturing process of a conventional type photovoltaic device; and

FIG. 14 are sectional views showing one manufacturing process of the conventional type photovoltaic device.

### DETAILED DESCRIPTION OF THE PREFERRED EMBODIMENTS

According to the invention, as described above, material for an impurity diffusion protecting layer is formed on the surface of a semiconductor substrate in a state in which the material is patterned, the number of heat treatment processes is reduced by forming a diffusion layer having an inverted pattern of the impurity diffusion protecting layer and the minority carrier lifetime of the semiconductor substrate can be prevented from being deteriorated. Further, the manufacturing cost can be also reduced by reducing an etching process.

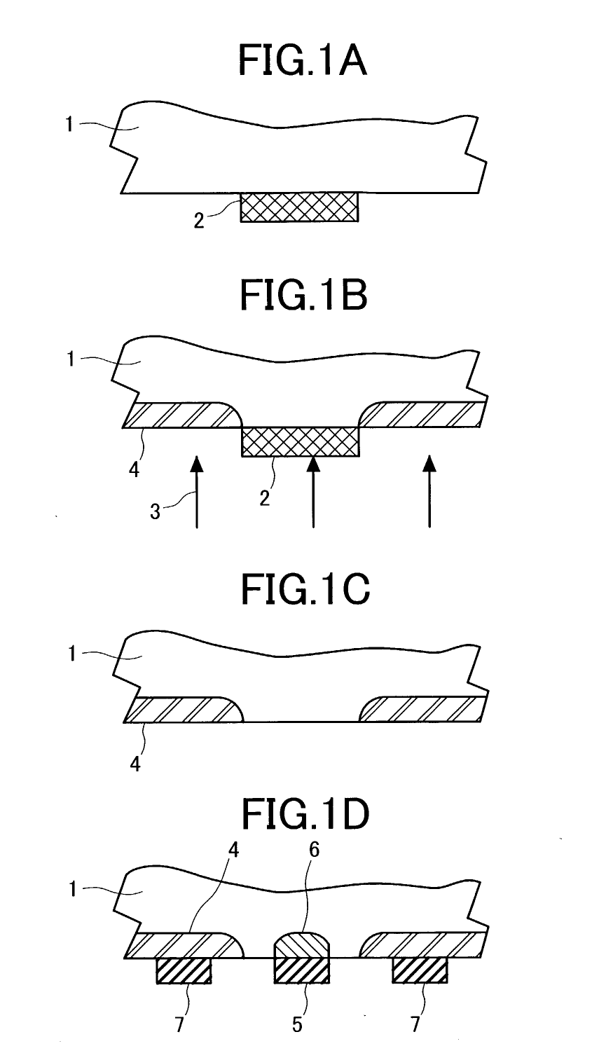

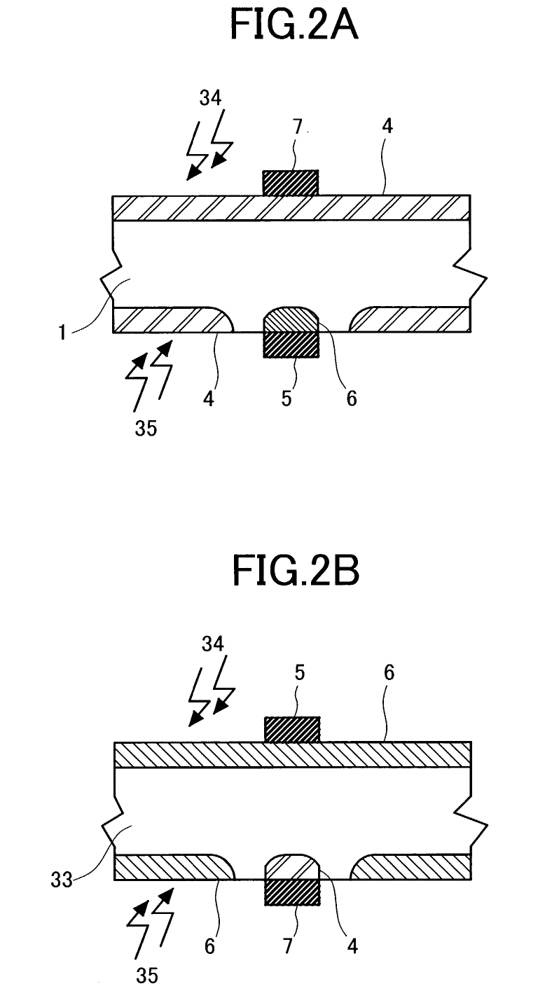

Referring to FIGS. 1 and 2, the principle of the invention will be described below.

FIG. 1 are process drawings showing one example of the making of a photovoltaic device according to the invention. First, as shown in FIG. 1A, high-viscosity paste including silicon oxide is printed and fired on one surface of a P-type silicon semiconductor substrate 1 in a pattern by screen printing and an impurity diffusion protecting layer 2 is formed. The firing temperature of the printed pattern is low temperature of approximately 400 C. and no deterioration of the minority carrier lifetime in the substrate 1 is caused.

Next, as shown in FIG. 1B, an N-type impurity layer 4 is selectively formed in a part where no impurity diffusion protecting layer 2 exists by gas phase diffusion using gas 3 including phosphorus which is impurities that function as an N type in silicon.

Next, as shown in FIG. 1C, the impurity diffusion protecting layer 2 is removed using the solution of a hydrofluoric acid.

Afterward, as shown in FIG. 1D, an aluminum electrode 5 is formed by printing and firing paste including aluminum in a pattern by screen printing and a P-type impurity layer 6 is formed under the electrode. A silver electrode 7 is formed as an electrode of the N-type impurity layer 4 by screen printing.

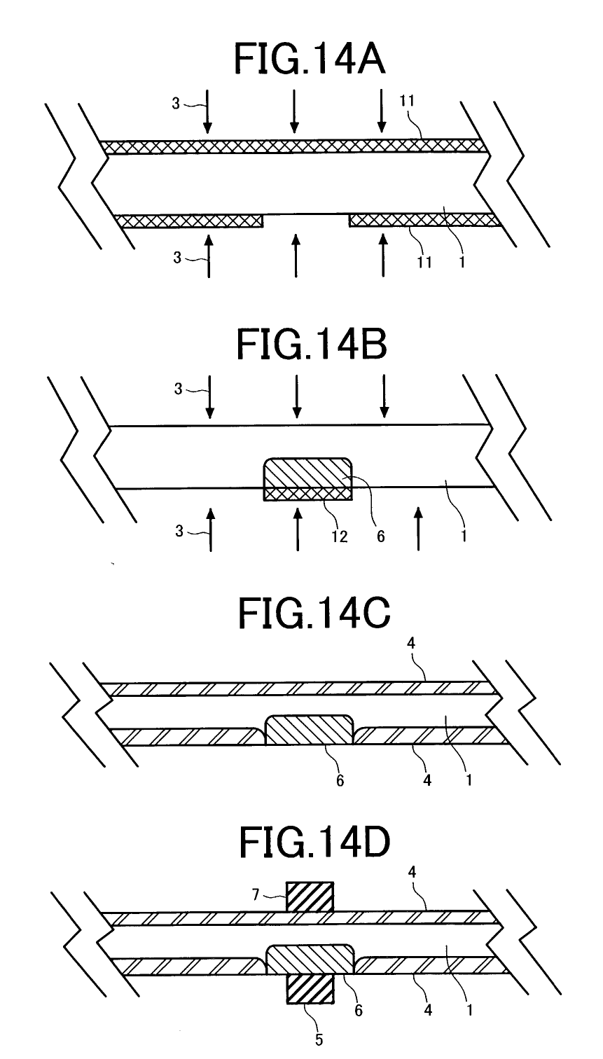

In the conventional type described referring to FIG. 14, the process for forming a film thermally oxidized at approximately 1000 C. on the surface of the semiconductor substrate and the process for forming an oxide film pattern by photolithography (including an etching process) are required, however, in the making according to the invention, as described above, the patterned diffusion layer 4 can be simply formed in only one process for forming the impurity diffusion protecting layer 2 including printing and firing a pattern.

The photovoltaic device having sectional structure shown in FIG. 2 can be formed by using the making. FIG. 2A is a sectional view showing the photovoltaic device manufactured using the P-type silicon semiconductor substrate 1. In this example, the photovoltaic device has structure that responds to both light 34 incident from the upside in FIG. 2A and light 35 incident on the back. The N-type impurity layer 4 and the electrode for an N type 7 are formed on the upper surface of the substrate, and the P-type impurity layer 6, the electrode for a P type 5 and the N-type impurity layer 4 connected to no electrode are formed on the lower surface (the back).

The structure of the lower surface shown in FIG. 2A is manufactured according to the making described referring to FIG. 1 and the N-type impurity layer 4 on the upper surface is formed simultaneously when the N-type impurity layer 4 on the lower surface is formed in the process shown in FIG. 1B.

As PN junction is formed between the N-type impurity layer 4 on the upper surface and the P-type substrate 1 in this structure, it is located in an upper part. Therefore, a response to the light 34 incident from the upside is higher than a response to the light 35 incident on the lower surface. The ratio of the response to the upper surface to the response to the lower surface greatly depends upon the minority carrier lifetime of the substrate 1 and others, and when the minority carrier lifetime of the substrate is long and as a result, the diffusion length of a minority carrier becomes approximately a triple of the thickness of the substrate 1, a response to the light 34 incident from the upside and a response to the light 35 incident on the lower surface become substantially similar. However, in the making according to the invention, as minority carrier lifetime is relatively short in a silicon substrate for a normal photovoltaic device though the deterioration of minority carrier lifetime is reduced by omitting heat treatment (the thermal oxidation of the surface of the substrate) at high temperature in the conventional type making, a response to the light 35 incident on the lower surface is smaller than that to the light 34 incident from the upside.

Then, a photovoltaic device of a type the conductive type of which is reverse to the structure shown in FIG. 2A, that is, having structure in which a P type and an N type are inverted and which is shown in FIG. 2B is manufactured using an N-type substrate the minority carrier lifetime of which is relatively long though the substrate has similar resistivity.

As a result, as shown in Table 1, open-circuit voltage and short-circuit current both have a larger value in the photovoltaic device manufactured using the N-type substrate and shown in FIG. 2B, compared with those in the photovoltaic device manufactured using the P-type substrate and shown in FIG. 2A.

The reason why the open-circuit voltage is high is that the minority carrier lifetime is mainly longer and the reason why the short-circuit current has a large value is that the carrier diffusion length is long. As a result, it proves that the photovoltaic device manufactured using the making according to the invention and having the structure according to the invention shows a higher characteristic by using the N-type substrate than a characteristic in case a P-type substrate is used.

TABLE 1

| | Open-circuit voltage | | | |
|---|---|---|---|---|
| | Irradiation | | Short-circuit current | |
| | of upper | Irradiation of | Irradiation of | Irradiation of |
| | surface | lower surface | upper surface | lower surface |
| P-type | 594 mV | 583 mV | 32.8 mA/cm² | 24.0 mA/cm² |
| substrate | | | | |
| N-type | 613 mV | 604 mV | 34.9 mA/cm² | 25.03 mA/cm² |
| substrate | | | | |

Embodiments

Referring to the drawings, embodiments of the invention will be concretely described below.

First Embodiment

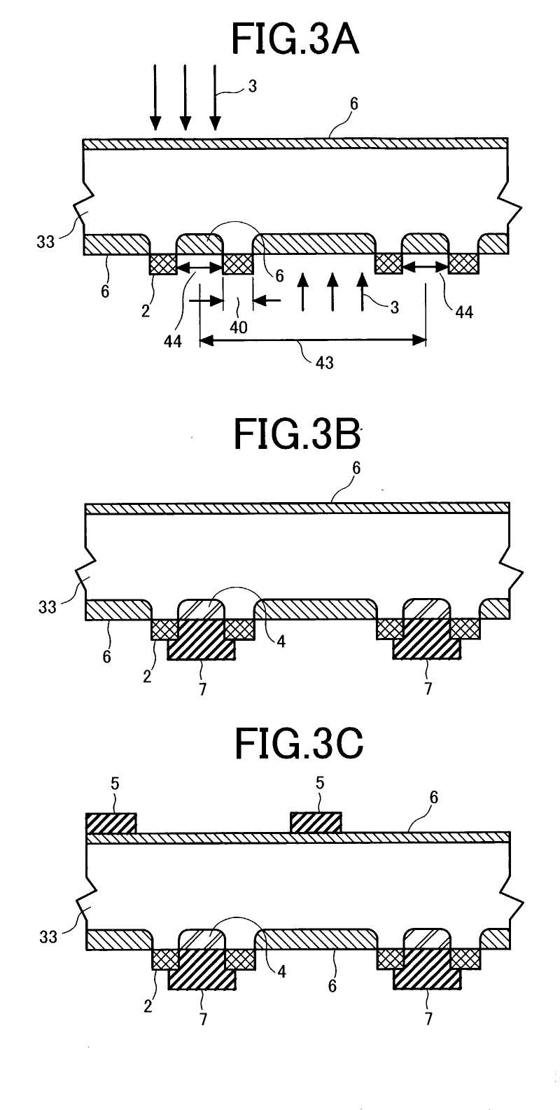

Referring to manufacturing process drawings shown in FIG. 3, an embodiment in which a photovoltaic device according to the invention is manufactured using an N-type substrate will be described below.

As shown in FIG. 3A, for a substrate 33, an N-type monocrystalline silicon substrate is used and an impurity diffusion protecting layer 2 having the width of 100 μm and having an opening 44 on the lower surface is formed so that pitch 43 between the impurity diffusion protecting layers is 2.5 mm. The impurity diffusion protecting layer 2 is acquired by printing and firing high-viscosity paste including silicon oxide in a pattern by screen printing and as the impurity diffusion protecting layer is mainly made of SiO₂, it has electric insulation performance.

Afterward, a P-type impurity layer 6 is formed on the lower surface by inserting the substrate 33 in the atmosphere at 1000 C. of diffusion gas 3 including boron which is a P-type impurity. A P-type impurity layer 6 is also simultaneously formed on the upper surface.

Next, as shown in FIG. 3B, after silver paste is printed in the opening 44 of the impurity diffusion protecting layer 2 according to a printing method, it is fired at 780 C. and a second electrode (a silver electrode) 7 for an N type is formed. For the formation of the electrode 7, antimony (Sb) is diffused in the substrate via the opening 44 by including Sb to be an N type in silicon in the silver paste beforehand simultaneously when the paste is fired, the impurity layer 6 is compensated and the N-type impurity layer 4 is formed.

As the impurity diffusion protecting layer 2 formed on the lower surface of the substrate has electric insulation performance, the electrode 7 and the P-type impurity layer 6 are electrically insulated. The case that antimony (Sb) which is relatively stable and is usable is used to form the N-type impurity layer 4 in the opening 44 is described above, however, it need scarcely be said that another material which has only to be an N type may be also used.

Further, as shown in FIG. 3C, a desired photovoltaic device is acquired by printing and firing a first electrode for a P type 5 over the upper surface of the substrate 33.

In the photovoltaic device having the structure described above, the ratio of the impurity diffusion protecting layer 2 to the whole area of the photovoltaic device is approximately 8%. Minority carriers are frequently recombined on an interface between the impurity diffusion protecting layer 2 and the silicon substrate 33. Therefore, when area which the impurity diffusion protecting layer 2 occupies is increased, the characteristics of the photovoltaic device such as open-circuit voltage and short-circuit current are deteriorated. When the occupied area exceeds 20%, the deterioration of open-circuit voltage becomes remarkable. Therefore, the ratio of the area which the impurity diffusion protecting layer 2 occupies is required to be 20% or less of the whole area of the photovoltaic device.

Short-circuit current out of responses to light incident on the lower surface substantially proportionally decreases as the ratio of the area which the impurity diffusion protecting layer 2 occupies increases. To reduce the manufacturing cost of the photovoltaic device per the quantity of power generation, the yield of short-circuit current to light incident on the lower surface is required to be increased possibly.

As current generated by the irradiation of the lower surface is less than current generated by the irradiation of the upper surface in most cases, the characteristics of the lower surface are required to be kept higher to equalize characteristics by the irradiation of the upper surface and characteristics by the irradiation of the lower surface and use the upper surface and the lower surface without distinction. For that purpose, it is desirable that the area of a part uncovered with the electrode 7 on the lower surface of the impurity diffusion protecting layer 2 formed on the lower surface is equivalent to 10% or less of the whole area of the photovoltaic device.

In this embodiment, the width of a part in which the electrode 7 on the lower surface is overlapped with a pair of impurity diffusion protecting layers 2 located on both sides is set to 100 μm. Therefore, the area of the part uncovered with the electrode 7 on the lower surface of a pair of impurity diffusion protecting layers 2 is 100 μm in total.

As pitch 43 between the impurity diffusion protecting layers 2 is 2.5 mm, the ratio of the area of the part uncovered with the electrode 7 on the lower surface of the impurity diffusion protecting layer 2 formed on the lower surface is equivalent to 4% of the whole area of the photovoltaic device. In comparison between current generated in case a prototype is formed using a wafer the minority carrier lifetime of which is relatively long and is irradiated from the upside using light of the same intensity and current generated in case the prototype is irradiated from the downside, the ratio of the current generated in case the lower surface is irradiated to the current generated in case the upper surface is irradiated is 95%.

In the above description, the representation of the upper surface and the lower surface is used, however, these are terms used to show positional relation in the drawings showing the sectional structure of the photovoltaic device and in case these photovoltaic devices are actually used or manufactured, they are not always used or manufactured with the upper surface on the upside. In the following description, they are similar.

Second Embodiment

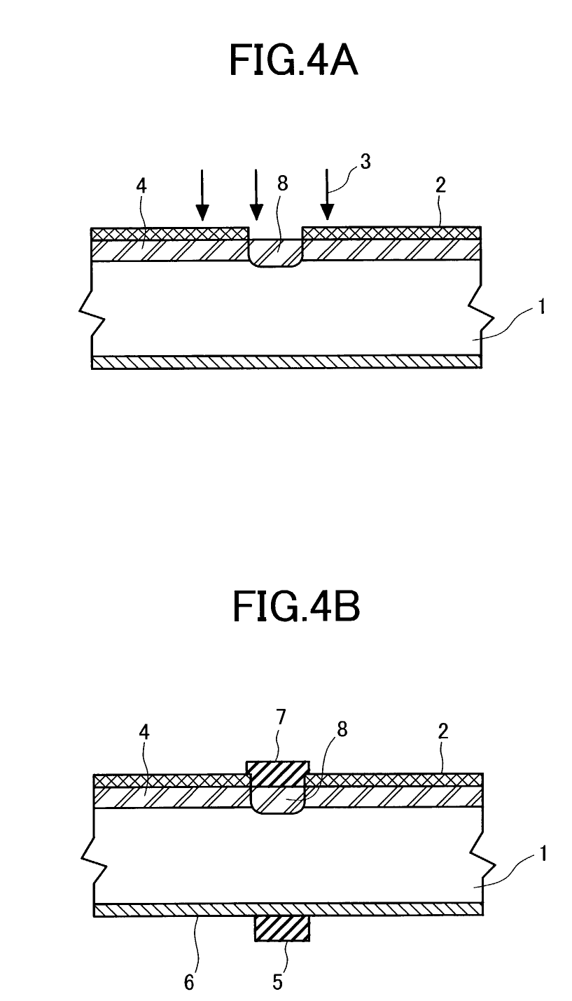

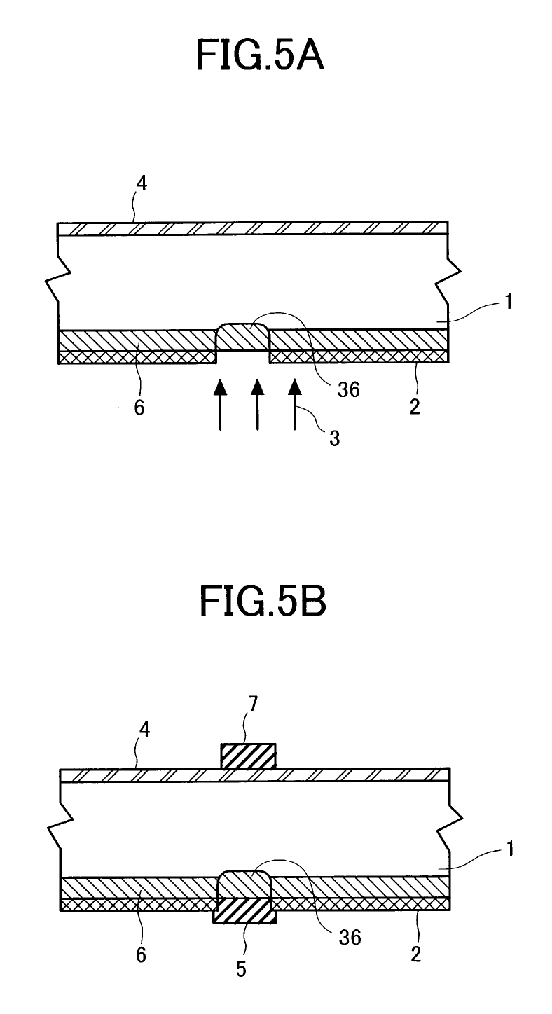

Referring to FIGS. 4 and 5, a second embodiment will be described below. First, FIG. 4 show a case that a two-stage emitter is manufactured using a P-type silicon substrate 1.

First, as shown in FIG. 4A, an impurity diffusion protecting layer 2 including phosphorus (P) that shows a conductive type of an N type in the silicon substrate is formed on the upper surface of the substrate 1 having a P-type diffusion layer 6 on the lower surface beforehand by printing and firing paste mainly made of silicon oxide and including phosphorus. The quantity of phosphorus included in the impurity diffusion protecting layer 2 is set to a value the sheet resistivity of which is to be approximately 50 Ω/□ (square) by heat treatment at approximately 900 C.

The diffusion gas 3 including phosphorus is applied from the upside of the substrate, impurities are diffused at 900 C. for twenty minutes, a first N-type diffusion layer 4 having the sheet resistivity of approximately 50 Ω/□ is formed under the impurity diffusion protecting layer 2 and a second N-type diffusion layer 8 having the sheet resistivity of approximately 10 Ω/□ is formed in an opening 44 of the impurity diffusion protecting layer 2.

Next, as shown in FIG. 4B, a silver electrode 7 for an N type is formed over the upper surface and an aluminum electrode 5 for a P type is formed over the lower surface respectively by the similar making to that in the first embodiment. As described above, a photovoltaic device having emitter structure that sheet resistivity is small (the density of impurities is high) in only a lower part of the electrode can be simply manufactured by using the impurity diffusion protecting layer 2 including impurities.

In the above description, the impurity diffusion protecting layer 2 is left as it is, however, if necessary, the impurity diffusion protecting layer 2 is removed and afterward, a reflection reducing film may be also formed. The case that the electrode 7 is wider than the opening of the impurity diffusion protecting layer 2 is described above, however, the opening is made wider than the electrode to reduce contact resistance between the electrode 7 and the silicon substrate 1 and the whole electrode 7 may be also put on the second N-type diffusion layer 8.

Sectional process drawings shown in FIG. 5 show a case that two-stage BSF structure is manufactured.

First, as shown in FIG. 5A, an impurity diffusion protecting layer 2 including boron (B) that shows a conductive type of a P type in the silicon substrate is formed on the lower surface of the P-type silicon substrate 1 having an N-type diffusion layer 4 on the upper surface beforehand by printing and firing paste mainly made of silicon oxide and including boron.

The quantity of phosphorus included in the impurity diffusion protecting layer 2 is set to a value the sheet resistivity of which is to be approximately 50 Ω/□ by heat treatment at approximately 950 C. Diffusion gas 3 including boron is applied from the downside of the substrate, impurities are diffused at 950 C. for thirty minutes, a first P-type diffusion layer 6 having the sheet resistivity of approximately 50 Ω/□ is formed under the impurity diffusion protecting layer 2 and a second P-type diffusion layer 36 having the sheet resistivity of approximately 5 Ω/□ is formed in an opening 44 of the first P-type diffusion layer.

Next, as shown in FIG. 5B, a silver electrode 7 for an N type is formed over the upper surface and an aluminum electrode 5 for a P type is formed over the lower surface respectively by the similar making to the case of FIG. 4.

As described above, a photovoltaic device having BSF structure that sheet resistivity is small (the density of impurities is high) in only a lower part of the electrode can be simply manufactured by using the impurity diffusion protecting layer including impurities.

The case that phosphorus is used for P-type impurities and boron is used for N-type impurities is described above, however, it need scarcely be said that even if another material having the similar conductive type is used, the similar structure can be acquired, and in case such material is suitably selected and used, the similar effect can be also acquired by manufacturing the structure described above using such material. In the structure in which a P type and an N type are suitably inverted in the above description, the similar effect to effect in the structure described above can be also acquired. These are also similar in the following description.

Third Embodiment

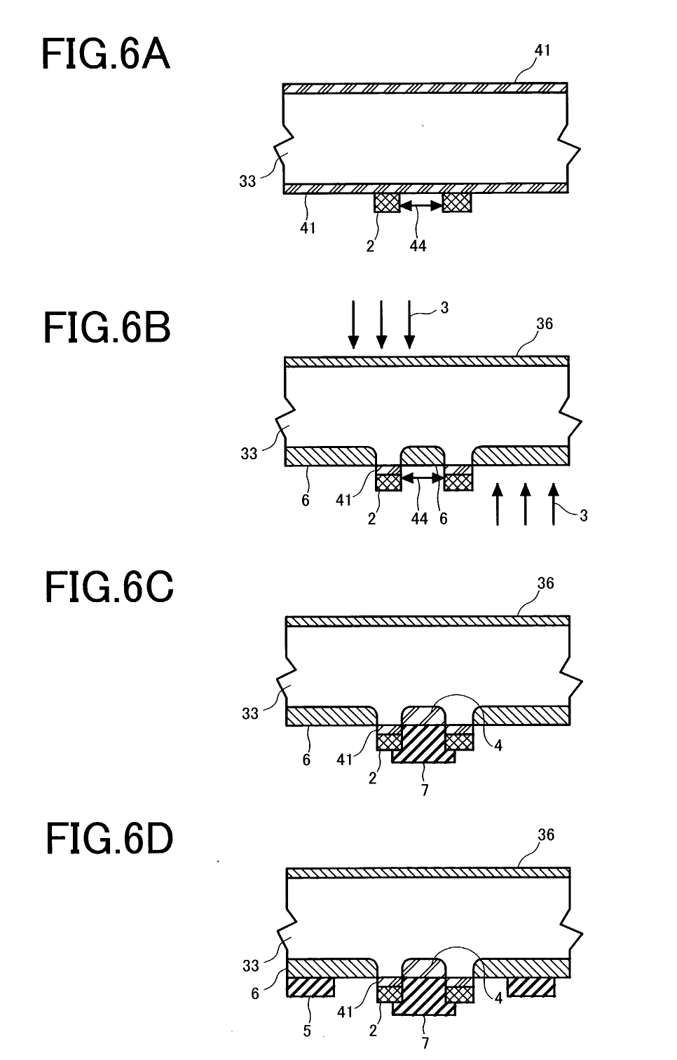

Referring to sectional process drawings shown in FIG. 6, a third embodiment will be described below. In this embodiment, as shown in FIG. 6A, a passivation film 41 approximately 20 nm thick is formed on the upper surface and the lower surface of an N-type silicon substrate 33 by thermal oxidation at approximately 800 C.

An impurity diffusion protecting layer 2 having an opening 44 is formed on the passivation film 41 by the similar making to that in the first embodiment, as shown in FIG. 6B, a first P-type impurity layer 6 is formed on the lower surface using diffusion gas 3 including boron as P-type impurities and a second P-type impurity layer 36 low in the density of impurities is formed on the upper surface using gas 3 low in the density of impurities. In the formation of these impurity layers, a part uncovered with a diffusion protecting layer of the thin passivation film 41 shown in FIG. 6A becomes impurity glass in diffusion and is left on the surface of the substrate in which impurities are diffused. In this embodiment, the part is removed by a dilute hydrofluoric acid, however, the part may be also left.

Next, as shown in FIG. 6C, an electrode 7 and an N-type layer 4 under the electrode 7 are simultaneously formed by printing and firing the material of an electrode (silver paste) including antimony (Sb) in an opening 44 of the impurity diffusion protecting layer 2 according to the similar making to that in the first embodiment.

Finally, as shown in FIG. 6D, an electrode 5 is formed on the first P-type impurity layer 6 on the lower surface by the similar making to that in the first embodiment.

Owing to such structure, the recombination of minority carriers between the impurity diffusion protecting layer and the silicon substrate is reduced is reduced and current generated by light incident on the lower surface is increased, compared with the structure without the passivation film 41. Open-circuit voltage also rises.

The effect described above is effect acquired because the passivation film 41 exists between the impurity diffusion protecting layer 2 and the silicon substrate, and the structure of the other part and the making are not essential. A method of forming the passivation film 41 is not limited to thermal oxidation described above, and the passivation film may also be an oxide film and an SiNx film formed by plasma CVD and further, may be also a passivation film having passivation structure made of cesium (Cs) and using an electric charge and hetero structure using a-Si or others.

It need scarcely be said that it is also effective to use the passivation film in this embodiment in structure in the following fourth and fifth embodiments.

Fourth Embodiment

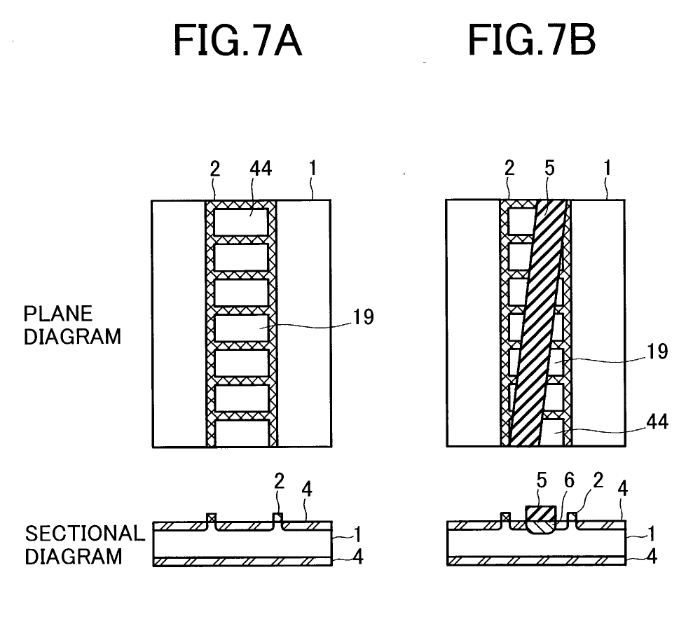

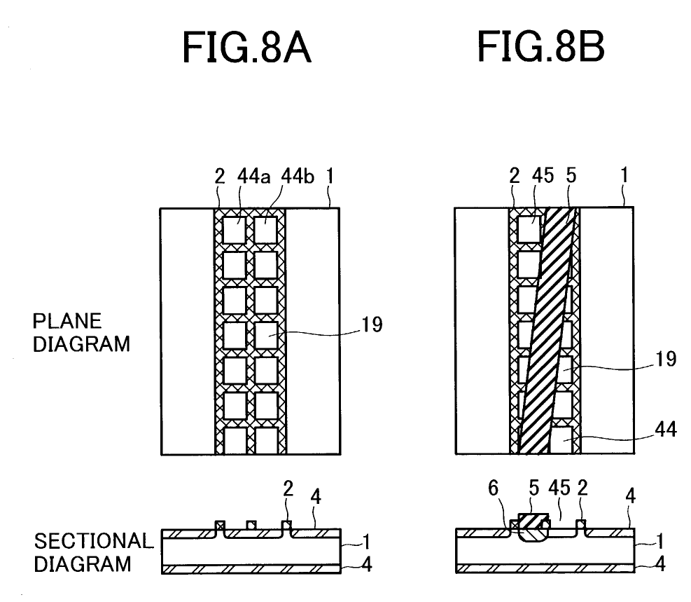

Referring to manufacturing process drawings shown in FIGS. 7 and 8, a fourth embodiment will be described below. A top view is shown on the upside in each drawing and a sectional view is shown on the downside in each drawing. In this embodiment, first as shown in FIG. 7A, an impurity diffusion protecting layer 2 having electric insulation performance is formed like a ladder on the upper surface of a P-type substrate 1 having a diffusion layer 4 on the lower surface by the similar making to that in the first embodiment, diffusion gas including phosphorus (P) is applied to the substrate using the impurity diffusion protecting layer as a mask and an N-type diffusion layer 4 is formed by the similar making to that in the second embodiment.

Next, as shown in FIG. 7B, the material of an electrode (aluminum paste in this embodiment) including impurities having a conductive type of an N type and having smaller width than the width of an opening 44 of the impurity diffusion protecting layer 2 is printed and fired, and a P-type aluminum electrode 5 and a P-type impurity layer 6 are simultaneously formed. As described above, as the impurity diffusion protecting layer 2 and the opening 44 are made wider than the electrode 5, the electrode 5 can be housed in a contact 19 even if the electrode slightly tilts or is slightly set off in printing. A subsequent process is not shown in FIG. 7, however, if necessary, as described in the first embodiment shown in FIG. 3, an electrode 7 such as a silver electrode for an N-type impurity layer 4 is formed and a photovoltaic device is manufactured.

However, in the above making, the area of the N-type impurity layer provided in the opening 44 of the impurity diffusion protecting layer 2 is large. As light incident on this part does not contribute to power generation, the photo-electric conversion efficiency of the photovoltaic device cannot be enhanced in this structure.

Then, as shown in FIG. 8A, an impurity diffusion protecting layer 2 having openings 44a and 44b forming two rows is formed. In this structure, as light incident on a floating N-type layer 45 being not in contact with the electrode 5 out of an N-type impurity layer in the opening contributes to power generation, the photo-electric conversion efficiency can be enhanced. The case that the openings are formed in two rows is described above, however, the area of the floating N-type layer is increased by increasing the number of rows more than two and further, the characteristics can be enhanced.

Fifth Embodiment

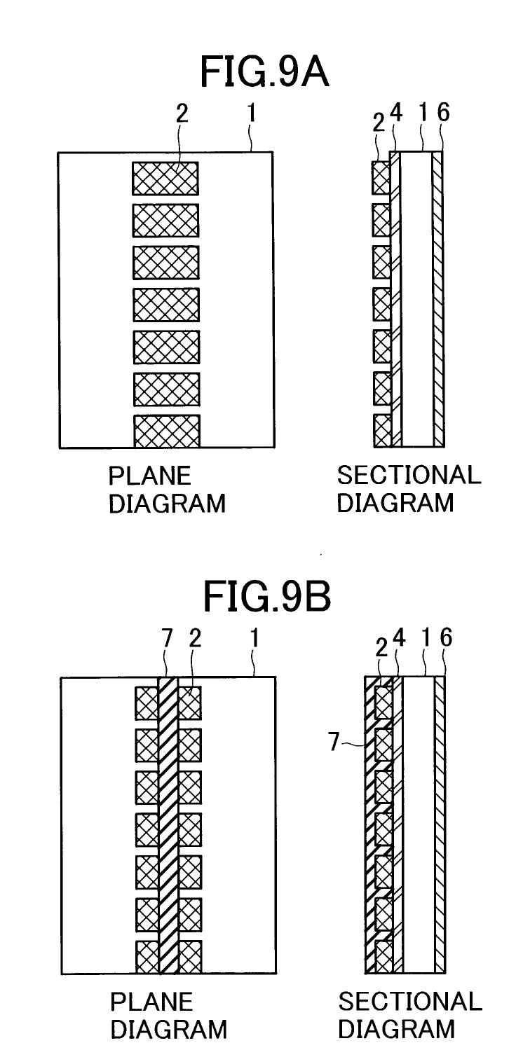

Referring to FIGS. 9A and 9B, a fifth embodiment will be described below. A top view is shown on the left side of each drawing and a sectional view is shown on the right side. In this embodiment, as shown in FIG. 9A, a P-type substrate 1 having a P-type impurity layer 6 on the lower surface and having an N-type impurity layer 4 on the upper surface is used and plural impurity diffusion protecting layers 2 are provided on the upper surface at an interval by the similar making to that in the first embodiment.

Afterward as shown in FIG. 9B, area in which an electrode 7 and the N-type impurity layer 4 are touched can be reduced by forming the electrode 7 on them. Though an electrode 5 is not shown, the electrode 5 is formed on the P-type impurity layer 6 if necessary and a photovoltaic device is manufactured.

As minority carriers in the part in which the electrode and the semiconductor layer are touched are recombined at high speed, open-circuit voltage is particularly deteriorated in case the area of the part is large. However, in the making in this embodiment, as the impurity diffusion protecting layer 2 exists on the N-type impurity layer 4 in the semiconductor layer, the area of the part in which the electrode and the N-type impurity layer 4 are touched can be reduced up to 20% or less, compared with a case that no impurity diffusion protecting layer exists and hereby, open-circuit voltage can be increased by approximately 10 mV.

Sixth Embodiment

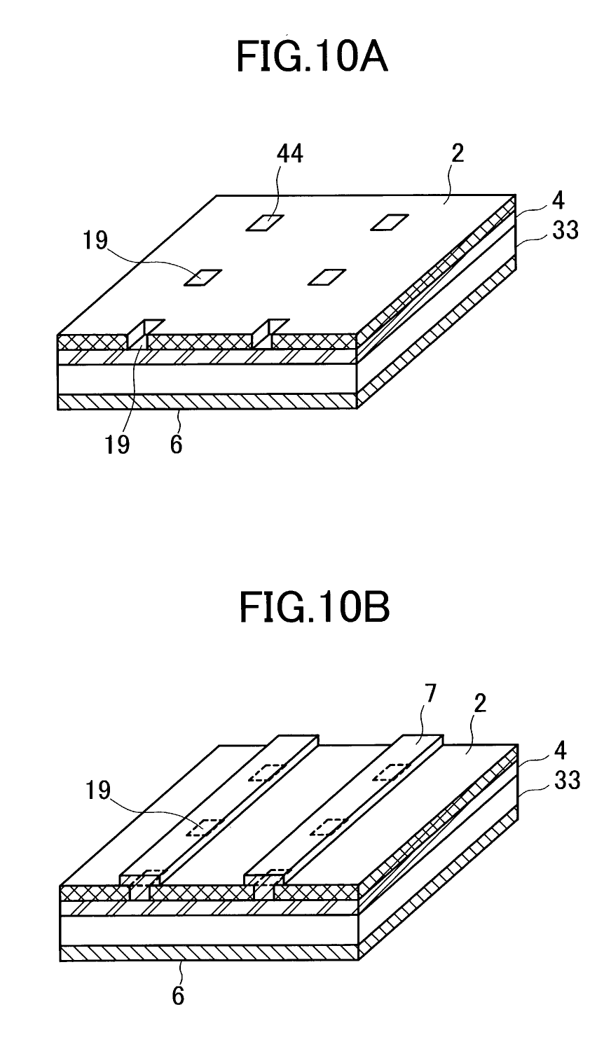

Referring to FIG. 10, a sixth embodiment will be described below. As shown in FIG. 10A, in this embodiment, an N-type substrate 33 having a P-type impurity layer 6 on the lower surface and having an N-type impurity layer 4 on the upper surface is used and an impurity diffusion protecting layer 2 is formed on the upper surface of the substrate as an insulating layer having plural openings 44 by the similar making to that in the first embodiment.

Afterward, the area of a part in which an electrode 7 and the N-type impurity layer 4 are touched can be reduced by forming the N-type electrode 7 as shown in FIG. 10B. Though the following electrode is not shown, the electrode for the P-type impurity layer 6 is formed if necessary and a photovoltaic device is manufactured.

As minority carriers in the part in which the electrode 7 and the N-type impurity layer 4 in the semiconductor layer are touched are recombined at high speed, open-circuit voltage is particularly deteriorated in case the area of the part is large. However, in the making in this embodiment, as the impurity layer is touched to the electrode 7 in only a contact region 19, the contact region can be further reduced, compared with that in the structure in the fifth embodiment.

A part of the electrode 7 can be overlapped with the contact 19 without aligning the openings and the electrode by not only providing the openings 44 under the electrode 7 shown in FIG. 10B but arranging the electrodes at an interval equal to or narrower than the width of the electrode 7.

The methods of forming the impurity diffusion protecting layers 2 described in the above embodiments are not limited to screen printing and ink-jet printing may be also used. A silicon oxide film may be also deposited from the upside of a metal mask using the mask by plasma CVD and thermic CVD.

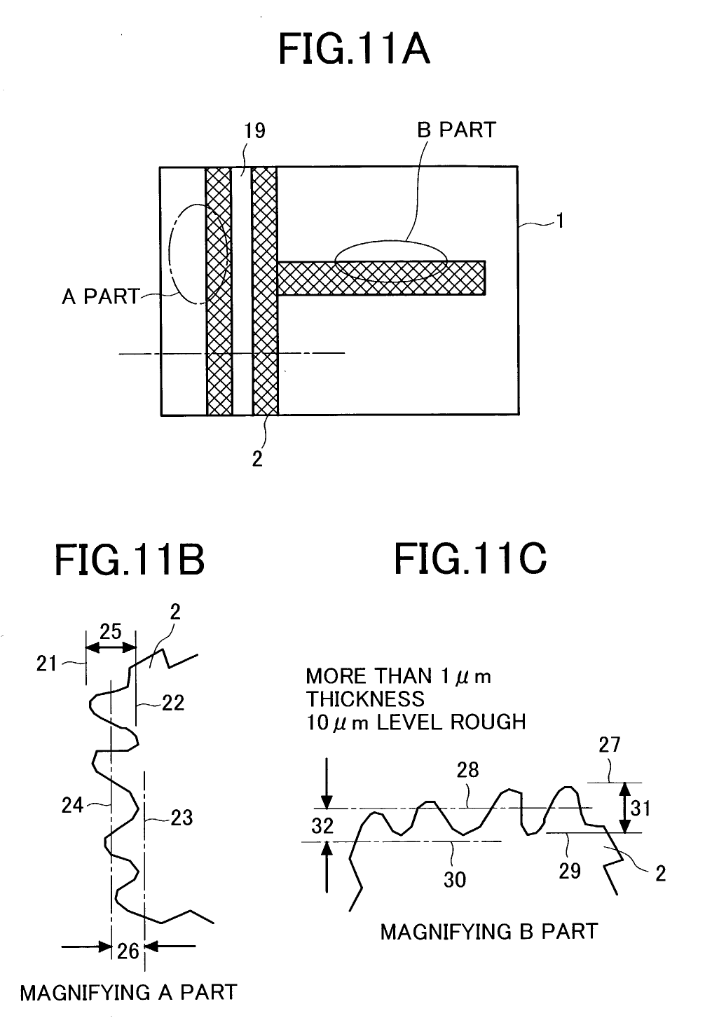

Also, an impurity diffusion protecting layer may be also formed by a silicon nitride film (an SiNx film). In case the impurity diffusion protecting layer is formed by the making according to the invention, a peculiar trend different from patterning according to conventional type photolithography appears. FIG. 11 schematically explain relation among the form and the position 23 of the impurity diffusion protecting layer 2 in pattern design, the actual contour and a mean position in the photovoltaic device according to the invention.

For example, in case an impurity diffusion protecting layer 2 having the form shown in FIG. 11A is printed, such irregularities that width 25 between an end face 21 at the leftmost end and an end face 22 at the rightmost end is 10 μm or more are made as shown in an enlarged view shown in FIG. 11B of a part A at the left end of a longitudinal pattern shown in FIG. 11A. Therefore, such irregularities that the width is 10 μm or more are also made in the peripheral contour along the end faces of a diffusion layer formed using the impurity diffusion protecting layer 2.

These irregularities are caused depending upon the precision of a printing screen mask and a metal mask, by the deformation of a printing screen caused by stress in printing and further, a drop of printing material. Generally, difference between irregularities in case photolithography is used is approximately 1 μm.

The mean position 24 of the contour at the left end is displaced on the left side by length 26 off the position 23 of the impurity diffusion protecting layer 2 in pattern design. This reason is that the relative positions of a printing screen or a metal mask and the semiconductor substrate 1 are displaced from a design value and in normal screen printing and normal printing using a metal mask, the displacement of approximately 20 μm or more is caused. Generally, displacement in case photolithography is used is approximately 1 μm.

In the case of screen printing, the occurrence of the blur of a pattern and a drop can be inhibited by setting the viscosity of paste material for manufacturing the impurity diffusion protecting layer 2 used for screen printing to fifty thousand to one million cp, desirably eighty thousand to four hundred thousand cp.

For a part B at the upper end of a lateral pattern shown in FIG. 11A, irregularities (width 31) having the similar pattern to the pattern shown in FIG. 11B and displacement 32 are also caused as shown in an enlarged view shown in FIG. 11C of the part B. Other reference numbers 27, 28, 29 and 30 respectively denote the uppermost part, a longitudinal mean position, the lowermost part and a longitudinal position in design. Therefore, pattern design in consideration of displacement is required.

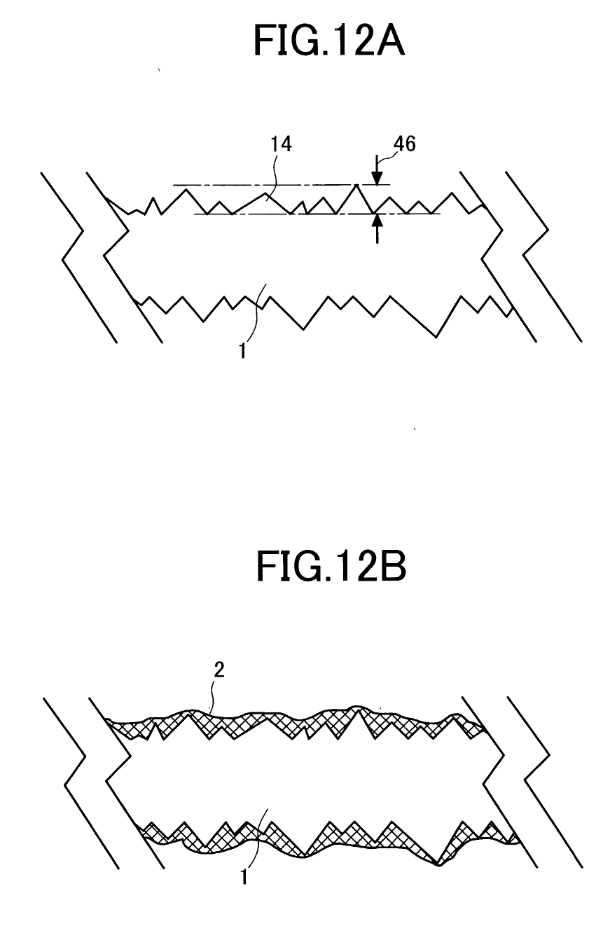

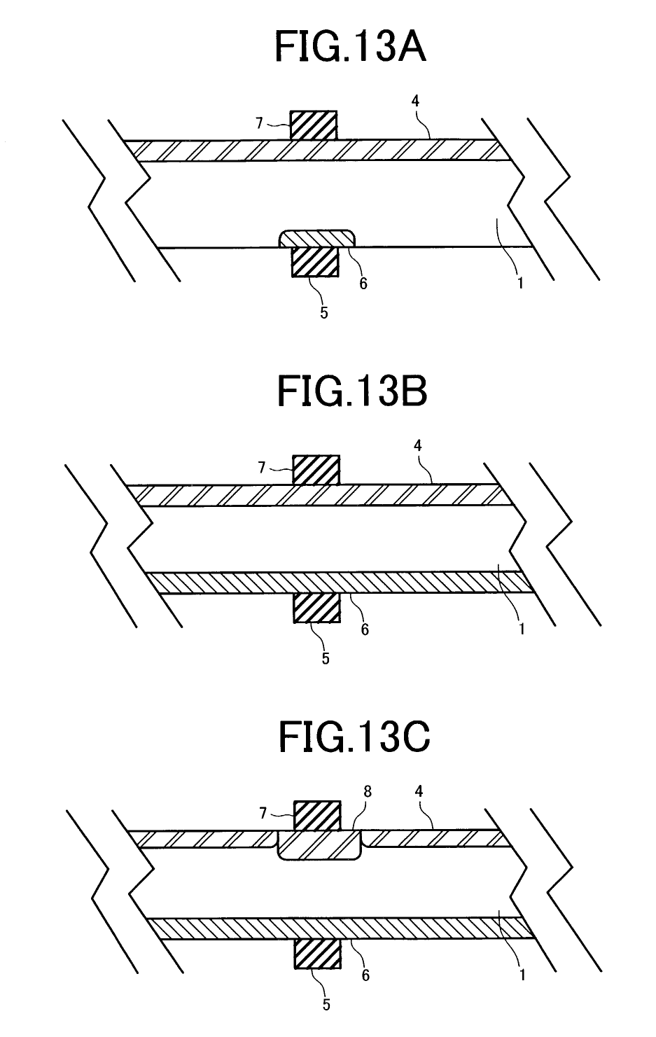

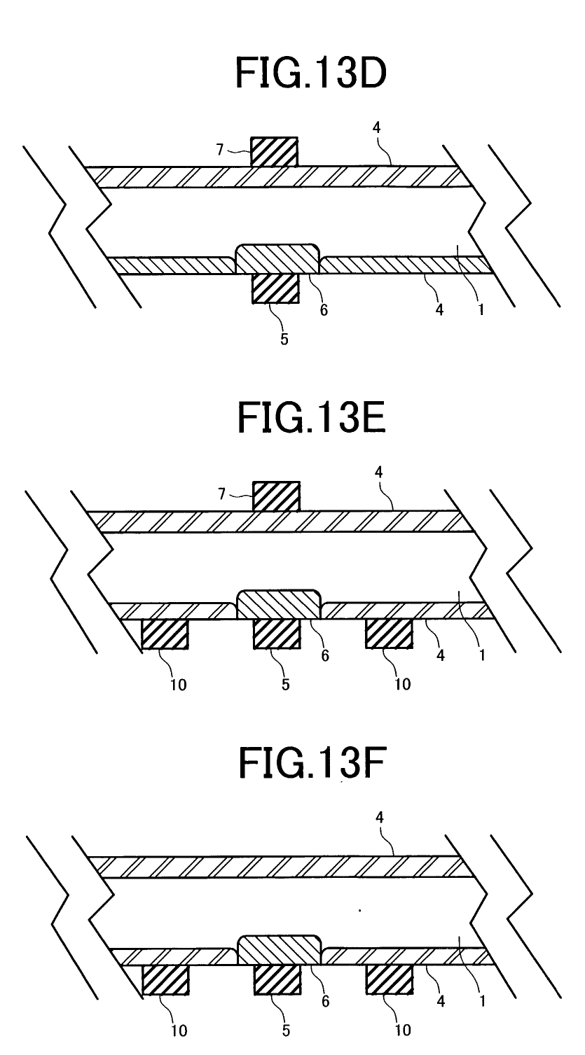

Though the following multiple irregularities are not described in the description of the first to fifth embodiments, multiple irregularities 14 the maximum value 46 in height of which is approximately 10 μm and the minimum value in height of which is approximately 3 μm as shown in FIG. 12A may be provided on the surface of the photovoltaic device to prevent light from being reflected on the surface. In this case, each vertex of the irregularities 14 can be covered with the impurity diffusion protecting layer 2 by setting the viscosity for example of the material of the impurity diffusion protecting layer 2 according to the invention to a large value.

The height 46 of the irregularities can be made 2 μm or less by forming the irregularities 14 by reactive ion etching (RIE). In this case, the impurity diffusion protecting layer 2 having the more precise form can be manufactured by forming the impurity diffusion protecting layer 2 using material low in viscosity so that the thickness is 1 μm or less.

For the formation of the electrodes 5 and 7, photolithography can be also used in addition to a method of directly forming a pattern such as screen printing.

For the semiconductor substrate, a monocrystalline or polycrystalline substrate made of silicon, germanium or gallium arsenide and having the shape of a polygon such as a circle and a quadrangle can be used. The conductive type of the semiconductor substrate may be also any of an i type, a P type and an N type. Various impurity layers and the conductive types of the semiconductor substrate may be variously combined as long as they compose the photovoltaic device. For impurities, phosphorus, arsenic, antimony (respectively N-type impurities), boron, aluminum and gallium (respectively P-type impurities) may be used.

As described in detail above, the object described above can be achieved according to the invention. That is, the low-priced photovoltaic device the photo-electric conversion efficiency of which is high can be realized.

What is claimed is:

1. A photovoltaic device, comprising:
an impurity diffusion protecting layer patterned on a semiconductor substrate;
a diffusion layer formed in an inverted pattern of the impurity diffusion protecting layer; and
an electrode formed in an opening of the impurity diffusion protecting layer, wherein:
the electrode is wider than the opening.

2. A photovoltaic device, comprising:
an impurity diffusion protecting layer patterned on a semiconductor substrate;
a diffusion layer formed in an inverted pattern of the impurity diffusion protecting layer;
a first electrode formed on the diffusion layer; and
a second electrode formed in an opening of the impurity diffusion protecting layer.

3. A photovoltaic device, comprising:
an impurity diffusion protecting layer patterned on a semiconductor substrate; and
a diffusion layer formed in an inverted pattern of the impurity diffusion protecting layer, wherein:
area which the impurity diffusion protecting layer occupies is equivalent to 20% or less of the whole area of the semiconductor substrate.

4. A photovoltaic device, comprising:
an impurity diffusion protecting layer including impurities patterned on a semiconductor substrate;
a first diffusion layer formed by the impurity diffusion protecting layer; and
a second diffusion layer formed in an inverted pattern of the impurity diffusion protecting layer and different in an impurity profile from the first diffusion layer.

5. A photovoltaic device, comprising:
an impurity diffusion protecting layer patterned on a semiconductor substrate; and
a diffusion layer formed in an inverted pattern of the impurity diffusion protecting layer, wherein:
a passivation layer is provided between the impurity diffusion protecting layer and the semiconductor substrate.

6. A photovoltaic device, comprising:
an impurity diffusion protecting layer patterned on a semiconductor substrate; and
a diffusion layer formed in an inverted pattern of the impurity diffusion protecting layer, wherein:
the impurity diffusion protecting layer is provided with openings in two or more rows along its shorter side.

7. A photovoltaic device, comprising:
an insulating layer patterned on a semiconductor substrate; and
an opening of smaller area than the area of an electrode under the electrode on the insulating layer.

8. A photovoltaic device according to claim 1, wherein:
a semiconductor substrate is made of N-type silicon; and
an electrode is formed in an opening of an impurity diffusion protecting layer.

9. A photovoltaic device according to claim 8, wherein:
the electrode includes N-type impurities; and
when the electrode is formed, an N-type diffusion layer is formed under the electrode on the semiconductor substrate.

10. A photovoltaic device according to claim 1, comprising:
a semiconductor substrate; and
an impurity layer which is formed on the semiconductor substrate and in the peripheral contour of which irregularities of 10 μm or more exist.
